(19) United States
(12) Patent Application Publication
(10) Pub. No.: US 2021/0074653 A1
(43) Pub. Date: Mar. 11, 2021

(54) Barriers for Flexible Substrates and Methods of Making the Same

(71) Applicants: Miki TRIFUNOVIC, San Jose, CA (US); Aditi CHANDRA, Los Gatos, CA (US); Robert FULLER, San Jose, CA (US); Raymond VASS, Bel Air, MD (US); Patricia BECK, San Jose, CA (US); Mao ITO, Santa Cruz, CA (US); Arvind KAMATH, Los Altos, CA (US)

(72) Inventors: Miki TRIFUNOVIC, San Jose, CA (US); Aditi CHANDRA, Los Gatos, CA (US); Robert FULLER, San Jose, CA (US); Raymond VASS, Bel Air, MD (US); Patricia BECK, San Jose, CA (US); Mao ITO, Santa Cruz, CA (US); Arvind KAMATH, Los Altos, CA (US)

(73) Assignee: Thin Film Electronics ASA, Oslo (NO)

(21) Appl. No.: 17/012,010

(22) Filed: Sep. 3, 2020

Related U.S. Application Data
(60) Provisional application No. 63/009,357, filed on Apr. 13, 2020.
(60) Provisional application No. 62/897,866, filed on Sep. 9, 2019.

(51) Int. Cl. H01L 23/00; H01L 21/56; H01L 23/14; H01L 23/15; H01L 23/29; H01L 23/31; H01L 21/48; B81B 7/00; H01L 27/12; H01M 2/02

(52) U.S. Cl. CPC H01L 23/564; H01M 2220/30; H01L 23/145; H01L 23/142; H01L 23/15; H01L 23/291; H01L 23/3135; H01L 21/481; B81B 7/0077; H01L 27/1218; H01L 27/1262; H01M 2/026; H01M 2/0275; H01M 2/0277; H01M 2/0287; H01L 21/56

(57) ABSTRACT

Embodiments of the disclosure pertain to a multi-layer barrier for a flexible substrate supporting electronic and/or microelectromechanical system (MEMS) devices. Apparatuses including a substrate, a first metal nitride layer, a first oxide layer on or over the first metal nitride layer, a second metal nitride layer and a second oxide layer on or over the first oxide layer, and a device layer on or over the first oxide layer or both the first and second oxide layers are disclosed. When the device layer is on or over the first oxide layer, the second metal nitride layer is on or over the device layer, and the second oxide layer is on or over the on or over the second metal nitride layer. When the device layer is on or over both the first and second oxide layers, the second metal nitride layer is on or over the second oxide layer. A method of making the same is also disclosed.

### RELATED APPLICATION(S)

The present application claims priority to U.S. Provisional Pat. Appl. Nos. 62/897,866, filed Sep. 9, 2019 (Atty. Docket No. IDR5320-PR), and U.S. Provisional Pat. Appl. No. 63/009,357, filed on Apr. 13, 2020 (Attorney Docket No. IDR2020-03-PR), each of which is incorporated herein by reference in its entirety.

### FIELD OF THE INVENTION

The present invention generally relates to the field of thin-film electronics. More specifically, embodiments of the present invention pertain to barriers for use on flexible substrates for thin-film circuitry (e.g., including transistors, capacitors, inductors, resistors, batteries and battery cells, etc.), and methods of making the same.

### DISCUSSION OF THE BACKGROUND

The use of flexible substrates in the electronics manufacturing industry has increased in popularity, and many challenges associated with their use have been addressed. However, several challenges remain.

One challenge is preventing or inhibiting undesirable substances that can impact electronic device performance from migrating to the electronic device from the substrate. For example, a known issue when using flexible polymer substrates is water vapor transmission through the substrate. These undesirable substances can impact electronic devices that are formed on the substrate. As a result, the properties of the devices change over time, and thus, the device lifetime can be reduced. For other types of substrates, such as metal substrates, other contaminants (e.g., within the metal substrate itself) must be effectively prevented from reaching the device layer, as these contaminants can also change device properties.

A second challenge involves the charge that accumulates at the substrate surface from substrate handling, cleaning and/or other process steps. The injection of charge into the device from the substrate causes uncontrollable changes in device performance, such as a shift in transistor threshold voltage, or charge carrier lifetime in solar cells.

A third challenge is the presence of defects on the substrate surface, caused by particles, dust, scratching, pinholes, etc. These defects on the substrate surface translate to defects in the devices that are built on top of the substrate. The larger the substrate, the greater the challenge(s).

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

Embodiments of the present invention relate to a multi-layer barrier for a thin film device substrate that addresses the challenges outlined above in the Discussion of the Background. To address the first challenge, the barrier layer may comprise materials that can block transmission of contaminants through the substrate and diffusion of other contaminants from the substrate, and that provides a pinhole-free surface. To address the second challenge, the barrier layer may control the level of charge on the substrate (and thus the amount of charge injection to such devices). To address the third challenge, the substrate and multi-layer barrier may further include a planarization layer (e.g., to provide a predetermined maximum surface roughness and ensure compliance with surface roughness requirements and/or specifications).

Thus, in one aspect, the present invention relates to an apparatus, comprising a substrate, a first metal nitride layer, a first oxide layer on or over the first metal nitride layer, a second metal nitride layer and a second oxide layer on or over the first oxide layer, and a device layer on or over the first oxide layer or both the first and second oxide layers. When the device layer is on or over the first oxide layer, the second metal nitride layer is on or over the device layer, and the second oxide layer is on or over the on or over the second metal nitride layer. When the device layer is on or over both the first and second oxide layers, the second metal nitride layer is on or over the second oxide layer.

In various embodiments of the apparatus, the substrate is flexible. For example, the substrate may comprise a polyimide, polyethylene naphthalate (PEN), polyethylene terephthalate (PET), copper, steel, aluminum, a glass, a silicone, or a flexible ceramic.

In other or further embodiments, each of the first and second metal nitride layers may independently comprise SiN, TiN, AlN, or a combination thereof. Alternatively or additionally, each of the first and second oxide layers may independently comprise SiO₂, a silicon-rich oxide, an aluminosilicate, a silicon oxynitride, an aluminum oxide, or TiO₂.

In various embodiments, the device layer may comprise an organic light-emitting diode (OLED), a solar cell, one or more microelectromechanical system (MEMS) devices, or a wireless communication circuit. When the device layer comprises the wireless communication circuit, the wireless communication circuit may comprise a radio frequency identification (RFID) or a near field communication (NFC) device.

In other or further embodiments, the device layer may comprise an integrated circuit (IC), an antenna, a battery, a battery cell, a display, or a sensor. When the device layer comprises the sensor, the sensor may comprise a temperature sensor, a humidity sensor, or a continuity sensor. When the device layer comprises the battery or battery cell, the battery or battery cell may comprise a solid-state battery or battery cell, such as a solid-state lithium battery or battery cell (SSLB). For example, suitable batteries and battery cells are disclosed in U.S. Provisional Pat. Appl. No. 63/009,357, filed on Apr. 13, 2020 (Attorney Docket No. IDR2020-03-PR), the relevant portion(s) of which are incorporated herein by reference.

Another aspect of the present invention relates to a method of manufacturing an apparatus, comprising forming a first metal nitride layer on a substrate, forming a first oxide layer on or over the first metal nitride layer, forming a second metal nitride layer and a second oxide layer on or over the first oxide layer, and forming a device layer on or over the first oxide layer or both the first and second oxide layers. When the device layer is formed on or over the first oxide layer, the second metal nitride layer is formed on or over the device layer, and the second oxide layer is formed on or over the on or over the second metal nitride layer. When the device layer is formed on or over both the first and second oxide layers, the second metal nitride layer is formed on or over the second oxide layer.

In various embodiments of the method, each of the first and second metal nitride layers and each of the first and second oxide layers are independently formed by atomic layer deposition (ALD), plasma-enhanced chemical vapor deposition (PECVD), low-pressure chemical vapor deposition (LPCVD), liquid vapor deposition (LVD), physical vapor deposition (PVD), inkjet printing, gravure printing, offset printing, flexography, nano-imprint printing, micro-contact printing, screen printing, stencil printing, spray-coating, blanket printing, dip-coating, blade-coating, or extrusion coating. In other or further embodiments, each of the first and second metal nitride layers and each of the first and second oxide layers are formed by roll-to-roll deposition. Thus, in some examples, the substrate may comprise a roll having a length of from 200 cm to 100 m and a width of from 5 to 100 cm (or any length and width, or ranges of lengths and widths, therein).

As for the apparatus, in some embodiments of the method, the substrate comprises a thermoplastic polymer, a metal foil, a polymer- or metal-coated paper, a siloxane polymer, or a ceramic, any of which may be flexible. In other or further embodiments, the substrate may comprise a sheet having a length of from 20 to 100 cm and a width of from 10 to 60 cm (or any length and width, or ranges of lengths and widths, therein).

A further aspect of the invention relates to an apparatus, comprising a substrate, a first metal nitride layer, a first oxide layer on or over the first metal nitride layer, either (i) an organic planarization layer or (ii) a gettering layer, and a device layer on or over the first metal nitride layer, the first oxide layer, and the organic planarization layer or gettering layer.

When the apparatus comprises the organic planarization layer, the organic planarization layer may comprise a coatable thermoplastic polymer. For example, the organic planarization layer may comprise a polyimide layer. In some embodiments, the organic planarization layer has a thickness greater than the combined thicknesses of the first metal nitride layer and the first oxide layer.

When the apparatus comprises the gettering layer, the gettering layer may protect the device layer from contaminants, ions, dangling bonds, and/or excess charges. For example, the gettering layer may include a plurality of trap states. In one embodiment, the gettering layer comprises amorphous silicon. In other or further embodiments, the gettering layer is adjacent to and in contact with the substrate or an uppermost one of the first metal nitride layer and the first oxide layer.

Typical devices that may benefit from this barrier layer include thin-film transistors (TFTs) made from materials such as low-temperature polycrystalline silicon (LTPS), organic semiconductors and metal oxide semiconductors (e.g., indium-gallium-zinc oxide [IGZO], a tin oxide (e.g., doped or undoped SnO₂), indium-zinc oxide [IZO], etc.), capacitors such as metal-insulator metal (MIM) capacitors and metal-insulator-semiconductor (MIS/MOS) capacitors, inductors, diodes, resistors, microelectromechanical system (MEMS) devices, thermoelectronics, piezoelectronics, batteries and battery cells, etc.

Applications that may benefit from the present invention include lighting (e.g., organic light-emitting diodes [OLED]), flexible displays, sensors, batteries, solar cells, MEMS devices, wireless communications, etc.

These and other advantages of the present invention will become readily apparent from the detailed description of various embodiments below.

### BRIEF DESCRIPTION OF THE DRAWINGS

FIG. 1 shows a multi-layer barrier between a substrate and a device layer, in accordance with one or more embodiments of the present invention.

FIGS. 2A-D show various spatial arrangements of the substrate and the barrier, in accordance with embodiments of the present invention.

FIG. 3 shows an alternative multi-layer barrier including a diffusion barrier layer and a charge-control layer between the substrate and the device layer, in accordance with one or more embodiments of the present invention.

FIG. 4 shows an alternative structure in which the device layer is enclosed between first and second multi-layer barriers on opposite surfaces of the device layer, in accordance with one or more embodiments of the present invention.

FIG. 5 shows a further alternative multi-layer barrier structure, in accordance with embodiments of the present invention.

FIG. 6 shows a further alternative structure including multiple multi-layer barriers, in accordance with one or more embodiments of the present invention.

FIG. 7 shows the structure of FIG. 6 further including an oxide planarization layer, in accordance with embodiments of the present invention.

FIGS. 8A-C show further alternative structures, each including an organic planarization layer in various spatial arrangements, in accordance with embodiments of the present invention.

FIG. 9 shows a substrate with a conductive layer underneath for electrostatic discharge (ESD) protection, in accordance with one or more embodiments of the present invention.

FIGS. 10A-B show alternative structures including a gettering layer for additional contaminant protection, in accordance with embodiments of the present invention.

FIGS. 11A-C show structures in a method of filling a hole in the multi-layer barrier with a metal, in accordance with embodiments of the present invention.

FIGS. 12A-B show structures in a method of patterning the substrate, in accordance with one or more embodiments of the present invention.

FIG. 13 shows alternative ways to pattern the substrate and the multi-layer barrier, in accordance with embodiments of the present invention.

FIGS. 14A-B show alternative structures including a resistive layer configured to evaporate water in the substrate, in accordance with embodiments of the present invention.

FIG. 15 is a cross-sectional view of an exemplary solid-state battery stack suitable as a device layer, according to an embodiment of the present invention.

FIG. 16 is a cross-sectional view of an exemplary solid-state battery stack having a multilayer solid-state electrolyte, according to another embodiment of the present invention.

FIG. 17 is a cross-sectional view of an exemplary solid-state battery stack having an alternative multilayer solid-state electrolyte, according to a further embodiment of the present invention.

FIG. 18 is a cross-sectional view of an exemplary solid-state battery stack having another alternative multilayer solid-state electrolyte, according to yet another embodiment of the present invention.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

The term “length” generally refers to the largest dimension of a given 3-dimensional structure or feature. The term “width” generally refers to the second largest dimension of a given 3-dimensional structure or feature. The term “thickness” generally refers to a smallest dimension of a given 3-dimensional structure or feature. The length and the width, or the width and the thickness, may be the same in some cases. A “major surface” refers to a surface defined by the two largest dimensions of a given structure or feature, which in the case of a structure or feature having a circular surface, may be defined by the radius of the circle.

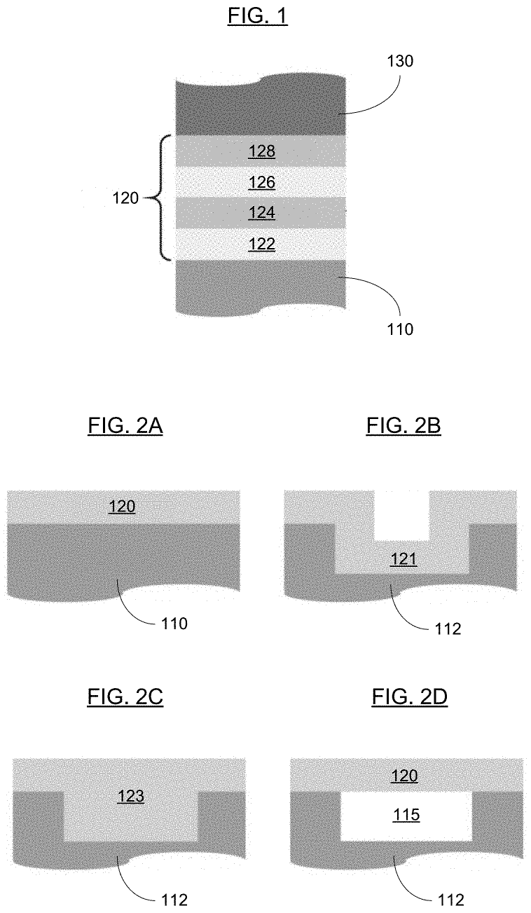

FIG. 1 shows a multi-layer structure including a flexible substrate 110, a multi-layer barrier 120, and a device layer 130. The multi-layer barrier 120 may comprise a first metal nitride layer 122, a first oxide layer 124, a second metal nitride layer 126, and a second oxide layer 128. The combined layers 122-128 together may function to block contaminants that can pass through the substrate 120 from reaching the device layer 130, buffer the device layer 130 from thermal energy absorbed by or passing through the substrate 120, control any charge that builds up or has built up on the substrate 120, and/or inhibit or prevent diffusion of atoms, ions or other chemical species from diffusing into the device layer 130 from the substrate 120. However, in the embodiment shown in FIG. 1 (and similar embodiments disclosed herein and/or shown in the drawings), the first metal nitride layer 122 may function to block contaminants that can pass through the substrate 120 from reaching the device layer 130, the first oxide layer 124 may buffer the device layer 130 from thermal energy absorbed by or passing through the substrate 120, the second metal nitride layer 126 may control any charge that builds up or has built up on the substrate 120, and the second oxide layer 128 may inhibit or prevent diffusion of atoms, ions or other chemical species from diffusing into the device layer 130 from the substrate 120. In some embodiments, there may be less than two metal nitride layers 122 and 126, and in other embodiments, there may be more than two metal nitride layers 122 and 126. Likewise, in some embodiments, there may be less than two oxide layers 124 and 128, and in other embodiments, there may be more than two oxide layers 124 and 128.

The substrate 110 may comprise a flexible sheet- or roll-based material (e.g., for scaled manufacturing). The substrate 110 may be or comprise a polymer sheet (e.g., comprising or consisting essentially of a polyimide, polyethylene naphthalate [PEN], polyethylene terephthalate [PET], derivatives, copolymers and/or blends thereof, etc.), a metal foil (e.g., comprising or consisting essentially of steel [e.g., stainless steel], copper, titanium, aluminum, etc.), a polymer- or metal-coated paper, a siloxane polymer, or a flexible ceramic. In some embodiments, the substrate 100 may comprise a combination of materials. For example, a polyimide film may be formed on a suitable metal foil (e.g., a metal that does not harm the polyimide properties, such as Mo or CrAl). In another example, a layer of metal may be deposited on a different substrate (such as polyimide) prior to forming the multi-layer barrier 120, which may limit the stretchability (e.g., elasticity) of the substrate 120.

The metal nitride layers 122 and 126 may be the primary components of the contaminant blocking and/or charge control functionality, although certain metal nitrides (e.g., TiN, AlN) are known diffusion barriers for certain metals, silicon, carbon, etc. Each of the metal nitride layers 122 and 126 may comprise SiN, TiN, AlN or a combination thereof (e.g., TiAlN), although aluminum oxides (e.g., Al₂O₃) may also be used in some examples, even though it is not a metal nitride. In some embodiments, the metal nitride layers 122 and 126 may be the same. In other embodiments, the metal nitride layer 122 and the metal nitride layer 126 comprise different materials.

The oxide layers 124 and 128 may provide thermal buffering and/or diffusion barrier functionality and/or may act as a planarization layer. Each of the oxide layers 124 and 128 may comprise SiO₂, a silicon-rich oxide (e.g., SiO_{z}, where 1.5≤z<2), an aluminum silicate (e.g., SiₐAl_{b}O_{c}, where c=2a+[4b/3]), a silicon oxynitride (e.g., SiOₓN_{y}, where x<2 and y=[4/3][2−x]), Al₂O₃ or other aluminum oxide (e.g., AlₓO_{y}), TiO₂ or a combination thereof. The oxide layers 124 and 128 function as thermal buffers during temperature-sensitive thermal annealing steps. For example, when laser-annealing a silicon sublayer in the device layer 130, the oxide layer(s) 124 and 128 may prevent excess heat diffusion from the silicon sublayer to the underlying substrate and protect a heat-sensitive substrate 120, such as those containing a thermoplastic polymer, aluminum, or paper.

Methods of depositing the layers of the barrier 120 include, but are not limited to, atomic layer deposition (ALD), plasma-enhanced chemical vapor deposition (PECVD), low-pressure chemical vapor deposition (LPCVD), liquid vapor deposition (LVD), or physical vapor deposition (PVD; e.g., evaporation, sputtering). Solution-based methods of depositing the layers of the barrier 120 may include printing (e.g., inkjet printing, gravure printing, offset printing, flexography, nano-imprinting, micro-contact printing, screen printing, stencil printing, etc.) or coating (spin-coating, spray-coating, blanket printing, dip-coating, blade-coating, extrusion coating, etc.). Such solution-based methods may be followed by a curing, hardening and/or densification step or process.

The multi-layer barrier 120 may be formed or deposited in a batch process on a sheet. In other embodiments, the barrier 120 may be formed or deposited in a roll-to-roll (R2R) process, in which case the substrate 110 may be or comprise a roll of polyimide or other thermoplastic polymer (e.g., PET or PEN), and layer deposition may then be performed using tools compatible with an R2R process. Parts of the barrier 120 may be selectively deposited (e.g., through a shadow mask) or blanket-deposited and subsequently patterned or partially removed. An R2R ALD process may be performed (e.g., at a relatively high temperature, but one compatible with the substrate 110) to increase the quality of the deposited layer. A thermal (e.g., heating or annealing) process following the layer deposition may further improve the quality of the deposited layer(s). The thermal process may be performed in a separate annealing tool (e.g., an R2R rapid thermal annealing [RTA] furnace or oven) or other type of furnace annealing tool. At least one R2R ALD tool also has the capability to heat or anneal the multi-layer barrier 120 on the substrate 110.

The device layer 130 may comprise circuitry for use in lighting (e.g., using organic light-emitting diodes [OLED]), displays, sensors, batteries, battery cells, solar cells, microelectromechanical systems (MEMS), wireless communication (e.g., radio frequency identification [RFID] or near field communication [NFC] devices), etc. For example, if the device layer 130 comprises circuitry for a wireless communication device, the device layer 130 may include an integrated circuit [IC] connected to an antenna, and optionally, a battery, a display and/or a sensor (e.g., a humidity or temperature sensor). Alternatively, the device layer 130 may comprise a battery, without an integrated circuit. In some embodiments, the sensor may include one or more continuity sensors that detect whether a package or container to which the device embodied by the device layer is attached has been opened or not (e.g., the package or container may be or comprise a box, a bottle, a jar, an envelope, a multi-well tray, etc.).

In one embodiment, the metal nitride layer 122 may comprise AlN (e.g., deposited by ALD), the oxide layer 124 may comprise an aluminosilicate (e.g., deposited by ALD), the metal nitride layer 126 may comprise AlN (e.g., deposited by ALD), and the oxide layer 128 may comprise SiO2 (e.g., deposited by PECVD). The metal nitride layer 126 can be selectively etched or deposited, and may be used to selectively change or influence the local charge at certain locations in the device layer 130 (e.g., an integrated circuit [IC]), and thus change device characteristics, such as thin-film transistor (TFT) threshold voltage. The metal nitride layer 122 and 126 and the oxide layer 124 (and, optionally, the oxide layer 128) may be deposited using ALD, without breaking the vacuum environment.

In another embodiment, the metal nitride layer 122 may comprise AlN (e.g., deposited by ALD), the oxide layer 124 may comprise SiO₂ (e.g., deposited by a spin-on-glass process using tetraethyl orthosilicate [TEOS] as a precursor), the metal nitride layer 126 may comprise AlN (e.g., deposited by ALD), and the oxide layer 128 may comprise SiO₂ (e.g., deposited by PECVD). A spin-on-glass oxide layer may have a slightly different chemical composition and different properties from essentially the same oxide layer formed by ALD or PVD. For example, the oxide layers 124 and 128 may be more effective planarization layers when formed by a solution-based glass deposition process (e.g., using a conventional spin-on-glass composition or formulation).

In yet another embodiment, the metal nitride layer 122 may comprise AlN (e.g., deposited by ALD), the oxide layer 124 may comprise an aluminosilicate (e.g., deposited by ALD), the metal nitride layer 126 may comprise AlN (e.g., deposited by ALD), and the oxide layer 128 may comprise SiO2 (e.g., deposited by a solution-based glass deposition process). As mentioned in the previous paragraph, the solution-based glass deposition oxide layer 128 may be an effective planarization layer.

In still another embodiment, the metal nitride layer 122 may comprise any of the aforementioned metal nitrides deposited by ALD, the oxide layer 124 may comprise any of the aforementioned oxides deposited by PECVD or ALD, and a second oxide layer (not shown) may be formed on the oxide layer 124 by a solution-based glass deposition process. The solution-based glass (precursor) layer may be blanket-coated or selectively coated (such as by slot die coating, blade-coating, extrusion coating, offset printing, flexography, spray-coating, microgravure printing, inkjet printing, screen printing, stencil printing, etc.) in an R2R process. A subsequent heating and/or annealing step may be used to drive off solvents and/or densify the film. Annealing at a high temperature may be performed when the substrate 110 is a polyimide or stainless steel, for example. For example, the deposited glass may be densified by annealing at a temperature≥600° C. (e.g., 800° C.) for a length of time≥60 minutes (e.g., 4 hours). The anneal may be done in oxygen, air, or nitrogen. An anneal in nitrogen may convert the deposited glass material to silicon nitride, while an anneal in air or oxygen converts the deposited glass material to SiO₂. In some embodiments (e.g., to form silicon nitride by annealing in nitrogen), a polysilazane layer may be used as the solution-based glass material.

In one embodiment, an oxide layer formed by a solution-based glass deposition process may first be deposited on the substrate 110 to form a planarization layer. The metal nitride layers 122 and 126 and the oxide layers 124 and 128 may then be deposited.

Although the substrate 110 is illustrated as being planar in FIG. 1, the substrate 110 may be non-planar. The substrate 110 may be patterned or pre-patterned in various patterns, and the multi-layer barrier 120 may cover the substrate 110 in various manners, depending on the application. FIGS. 2A-D show various spatial arrangements of the substrate 110 and the multi-layer barrier 120.

For example, FIG. 2A shows a planar substrate 110 and multi-layer barrier 120. FIG. 2B shows a “conformal coverage” embodiment, where the multi-layer barrier 121 (structurally similar to the multi-layer barrier 120 of FIG. 1) conforms to the surface of a patterned substrate 112, including the surface of a trough or cavity in the substrate 112. Due to its conformality, the barrier 120 may also have a trough or cavity therein.

FIG. 2C shows a planarized or planar coverage embodiment, where one or more layers of the multi-layer barrier 123 is/are deposited to form a flat or planar uppermost surface, thereby filling the trough or cavity in the substrate 112. The barrier 123 is also structurally similar to the multi-layer barrier 120 of FIG. 1.

FIG. 2D shows a “tenting coverage” embodiment, where the barrier 120 forms a layer over a void or cavity 115 in the substrate 112. The barrier 120 (which may be structurally identical to the multi-layer barrier 120 of FIG. 1 or any other multi-layer barrier disclosed herein) has a flat or planar uppermost surface in the embodiment of FIG. 2D. Certain devices can be advantageously made (e.g., “air” capacitors, MEMS devices) using the “tenting” embodiment of FIG. 2D.

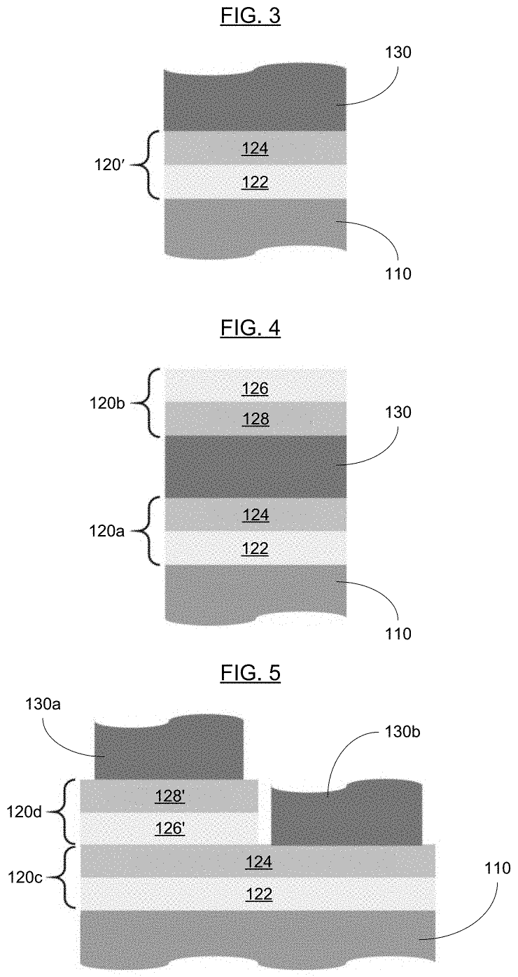

FIG. 3 shows an alternative structure including the substrate 110, a multi-layer barrier 120′, and the device layer 130. The barrier 120′ may comprise a metal nitride layer 122 and an oxide layer 124, as described previously. For example, the metal nitride layer 122 may comprise AlN (e.g., deposited by ALD), and the oxide layer 124 may comprise SiO₂ (e.g., deposited by a spin-on-glass process). In this embodiment, the metal nitride layer 122 may be a contaminant-blocking and/or charge-control layer, and the oxide layer 124 may be a thermal buffer, planarization and/or diffusion barrier layer.

FIG. 4 shows an alternative structure including the substrate 110, first and second multi-layer barriers 120a and 120b, and the device layer 130. In this embodiment, the first multi-layer barrier 120a is between the device layer 130 and the substrate 110, and the second multi-layer barrier 120b is on the opposite side of the device layer 130 from the first multi-layer barrier 120a. The first multi-layer barrier 120a may comprise the metal nitride layer 122 and the oxide layer 124, and the second multi-layer barrier 120b may comprise the oxide layer 128 and the metal nitride layer 126. However, in the second multi-layer barrier 120b, the oxide layer 128 and the metal nitride layer 126 are in reverse sequence. In other words, the oxide layer 128 is formed or deposited on an uppermost layer of the device layer 130, and the metal nitride layer 126 is formed or deposited on the oxide layer 128. In this configuration, contaminants may be blocked from both major surfaces of the device layer 130, and charge may be controlled both above and below the device layer 130.

FIG. 5 shows a further alternative structure including the substrate 110, first and second multi-layer barriers 120c and 120d, and device layers 130a and 130b. The first multi-layer barrier 120c may comprise the metal nitride layer 122 and the oxide layer 124 (as described herein), and the second multi-layer barrier 120d may comprise a metal nitride layer 126′ and an oxide layer 128′. The metal nitride layer 126′ may be chemically identical to the metal nitride layer 126 described above, and the oxide layer 128′ may be chemically identical to the oxide layer 128 described above. Each of the metal nitride layer 126′ and oxide layer 128′ may be made by the same processes as the metal nitride layer 126 and the oxide layer 128, respectively.

Selective deposition or etching of the barrier 120d may control the properties of the devices in device layers 130a and 130b in different locations of the substrate 110. Either a plurality of blanket layers comprising both multi-layer barriers 120c and 120d is locally patterned to form the second multi-layer barrier 120d, or the layers of the multi-layer barrier 120d are selectively deposited onto the barrier 120c in one or more predetermined and/or desired regions. The barrier 120d may thus be deposited by wet methods such as inkjet printing, screen printing, flexography, offset-printing, gravure-printing, stencil printing, micro-contact printing, or nano-imprinting. Alternatively, the barrier 120d may be deposited by dry methods, such as shadow mask deposition, blanket deposition on a patterned photoresist with subsequent lift-off, or blanket deposition followed by (low-resolution) photolithographic patterning.

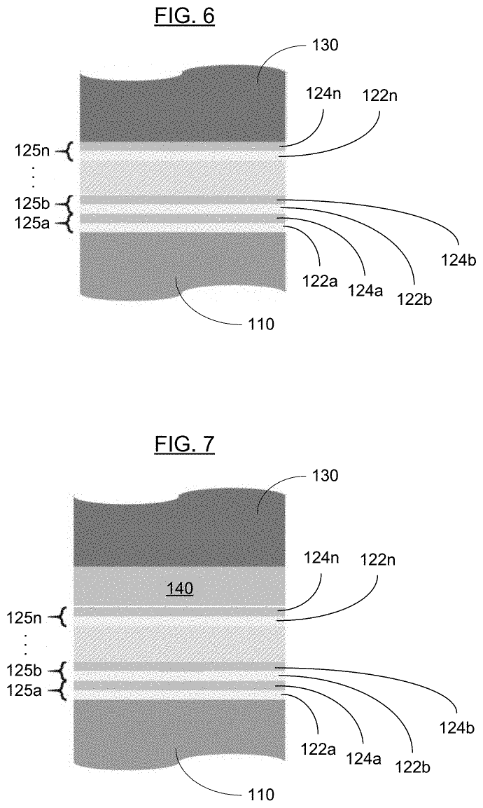

FIG. 6 shows an even further alternative structure including the substrate 110, a plurality of multi-layer barriers 125a-n, and the device layer 130. The structure may thus comprise n multi-layer barriers 125a-n, wherein n is an integer of 2 or more (e.g., 3-100 or more). Each of the barriers 125a-n may comprise a metal nitride layer and an oxide layer, as described herein. Thus, the first barrier 125a may comprise a metal nitride layer 122a and an oxide layer 124a, the second barrier 125b may comprise a metal nitride layer 122b and an oxide layer 124b, and the nth barrier 125n may comprise a metal nitride layer 122n and an oxide layer 124n. There may be (and typically is) one or more additional barriers 125c-m between the second barrier 125b and the nth barrier 125n, each respectively having a metal nitride layer 122c-m and an oxide layer 124c-m.

The multiple barriers 125a-n ensure that no pinhole defects allow water to be transported from the substrate 110 to the device layer 130. Each of the barriers 125a-n may alternate between different pairs of metal nitride and oxide layers. For example, in the first barrier 125a, the metal nitride layer 122a may comprise AlN, and the oxide layer 124a may comprise a silicon-rich oxide. In the second barrier 125b, the metal nitride layer 122a may comprise AlN, and the oxide layer 124b may comprise SiO₂. In the third barrier layer 125c, the metal nitride layer 122c may comprise AlN, and the oxide layer 124c may comprise an aluminum oxide (e.g., Al₂O₃). The multiple barriers 125a-n may be manufactured as thin as possible to maximize the flexibility of the structure.

FIG. 7 shows a variation of the structure of FIG. 6, including the substrate 110, the multi-layer barriers 125a-n, and the device layer 130. However, the structure of FIG. 7 further includes a relatively thick oxide layer 140 between the barrier stack 125a-n and the device layer 130. The oxide layer 140, which may comprise any dielectric or insulating oxide disclosed herein, is thicker (e.g., by 5-100 times) than any of the oxide layers 124a-n in the barrier stack 125a-n. In the structure of FIG. 7, either or both of the uppermost oxide layer 124n and/or the oxide layer 140a may function as a planarization layer. Additionally, the oxide layer 140a may further inhibit the diffusion of contaminants from the substrate into the device layer 130.

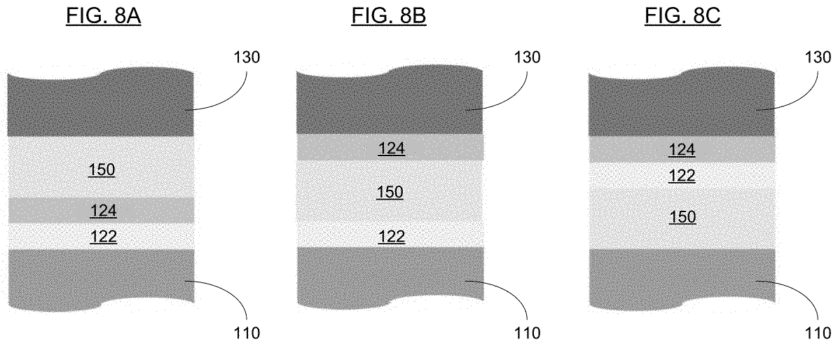

FIGS. 8A-C show alternative structures substantially similar to the structure of

FIG. 3, including the substrate 110, the metal nitride layer 122, the oxide layer 124, and the device layer 130. However, the structures of FIGS. 8A-C further include an organic layer 150. The organic layer 150 may be formed on, in or below the multi-layer barrier, and may serve as a planarization layer, alone or in combination with the oxide layer 124. The organic layer 150 may comprise any coatable organic material (e.g., a thermoplastic polymer), but in some embodiments, comprises a polyimide layer. The organic layer 150 may be between the oxide layer 124 and the device layer (FIG. 8A), between the metal nitride layer 122 and the oxide layer 124 (FIG. 8B), or between the substrate and the metal nitride layer 122 (FIG. 8C). The organic layer may be similarly added to other structures disclosed herein (e.g., those of FIGS. 1, 5, 6, etc.).

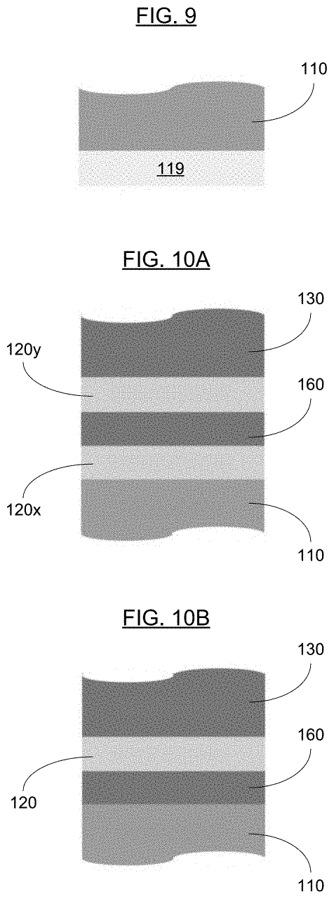

FIG. 9 shows a part of a structure including the substrate 110 and a metal nitride layer 119 deposited on an underside the substrate 110. The metal nitride layer 119 may function as an electrostatic discharge (ESD) layer, which may be advantageous when the structure (i.e., the substrate, multi-layer barrier and device layer as disclosed herein) is in the form of a roll (e.g., electrostatic energy may form or accumulate on the substrate when processing [e.g., rolling or unrolling] the roll). The metal nitride layer 119 may comprise TiN or any other metal nitride described with respect to the metal nitride layers 122 and 126 in FIG. 1. The metal nitride layer 119 is not limited to the structure shown in FIG. 9, and may be deposited on the major surface of the substrate 110 opposite from the multi-layer barrier in any of the embodiments described herein.

FIGS. 10A-B show structures substantially similar to the structure of FIG. 1, including the substrate 110, the multi-layer barrier 120, and the device layer 130. However, the structures of FIGS. 10A-B further include a gettering layer 160. The gettering layer 160 functions as a conventional gettering layer (e.g., it further protects the device layer 130 from contaminants, ions, dangling bonds, excess charges, etc.). The gettering layer 160 may be deposited by PECVD, and may include trap states (e.g., to effectively capture the contaminants, ions, or excess charges, neutralize any dangling bonds, etc.). The gettering layer 160 may comprise amorphous silicon (a-Si). When the gettering layer 160 comprises a-Si, it may be advantageous to prevent excess heat from reaching the a-Si layer, to maintain the level of trap states inside the material. The gettering layer 160 may be between two multi-layer barriers 120x-y (FIG. 10A), or between the substrate 110 and the multi-layer barrier 120 (FIG. 10B).

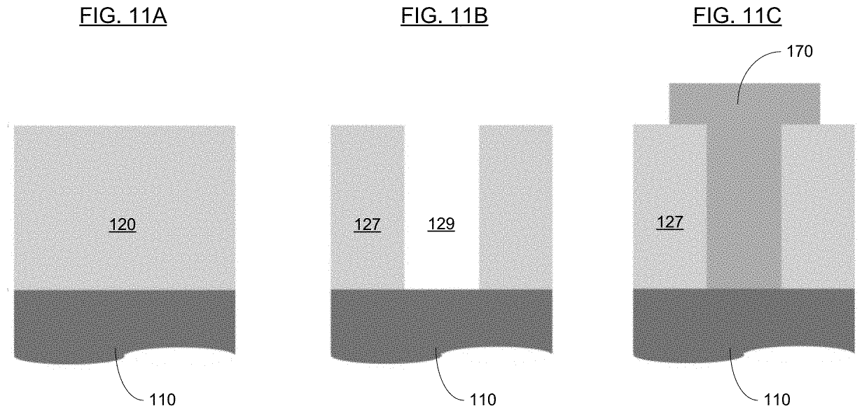

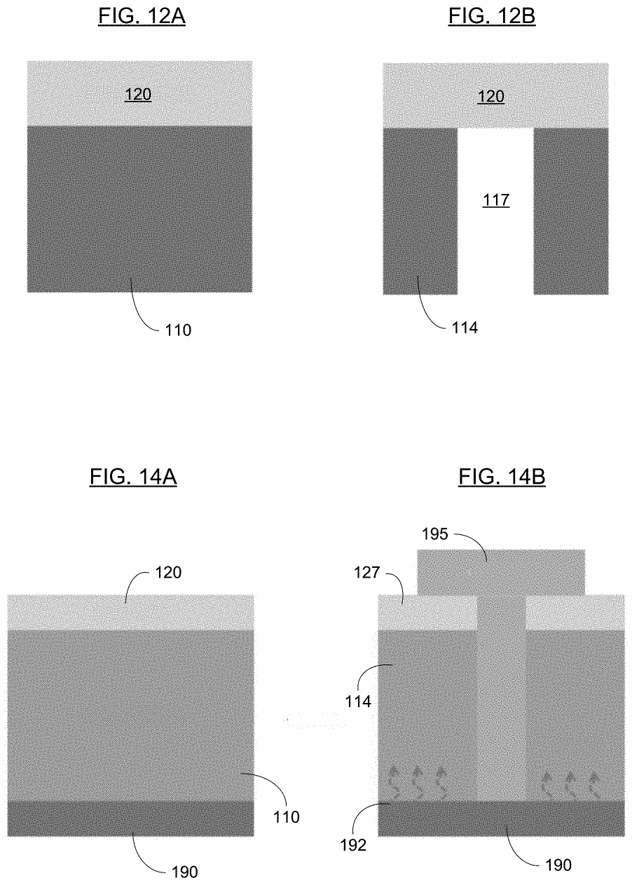

FIGS. 11A-C show structures formed in an exemplary process for forming an opening in the multi-layer barrier 120 to expose the surface of the substrate 110. Starting from the substrate 110 and the blanket-deposited multi-layer barrier 120 (FIG. 11A), the barrier 120 is ablated (e.g., by irradiation) by a laser pulse, which forms a hole or opening 129 that exposes the surface of the substrate 110 (FIG. 11B), forming a patterned barrier 127. This process may be particularly advantageous when the substrate 110 comprises a metal such as steel (e.g., stainless steel). Alternatively, the hole 129 may be formed by etching (e.g., dry etching, wet etching, or a combination of both, using a patterning mask such as a patterned photoresist).

The hole 129 may be subsequently filled (e.g., by PVD, CVD, etc., followed by patterning and/or planarization) by a metal plug or contact 170. The accessibility of an electrically conducting substrate 110 to the subsequently-formed device layer (not shown in FIGS. 11A-C) may allow applications in which the electronic device layer 130 can access a relatively large ground plane (e.g., when the substrate 110 is held at a ground potential by an external device or other electromagnetic force), or formation of sensors that use a change in the physical and/or chemical behavior of the substrate 110 by external energy sources.

FIG. 12A shows the substrate 110 and the multi-layer barrier 120. In FIG. 12B, a pattern may be formed in the substrate 110 by wet or dry etching (e.g., following photolithographic patterning and development of a photoresist), thereby forming a patterned substrate 114 (FIG. 12B). in such a process, the lowest layer of the barrier 120 (i.e., nearest or adjacent to the substrate 110) may be used as an etch-stop layer. For example, when the substrate 110 comprises stainless steel, the substrate 110 may be etched with FeCl₃ (e.g., aqueous FeCl₃, which may further contain HCl or another acid), and the etching may stop at a lowermost the AlN layer in the barrier 120. Such substrate patterning may be used in applications where the substrate 110 is advantageously thin in predetermined areas or regions (e.g., to generate certain mechanical properties). Such substrate patterning may also be used to isolate (e.g., electrically or mechanically) metal features (such as capacitor plates and/or antenna/inductor coils) created in the substrate 110.

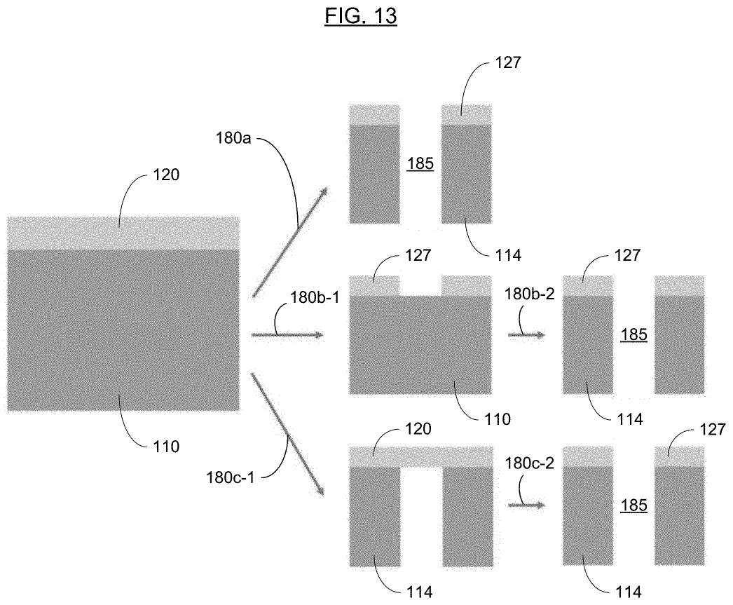

FIG. 13 shows a variety of different processes 180a-c for patterning the combined substrate 110 and barrier 120. Such patterning can be performed by laser ablation, photolithographic patterning and etching (wet or dry), or a combination of laser ablation and photopatterning/etching. Patterning both the substrate 110 and the barrier 120 may be useful in the formation of micro-electromechanical systems (MEMS) and microfluidics devices.

In process 180a, both the substrate 110 and the barrier 120 may be patterned in one step to form a patterned substrate 114 and patterned barrier 127. Alternatively, in process 180b, the barrier 120 is patterned in a first step 180b-1 to form the patterned barrier 127, and then the substrate 110 is patterned in a second step 180b-2 to form the patterned substrate 114. In a further alternative, in process 180c, the substrate 110 is patterned in a first step 180c-1 to form the patterned substrate 114, and the barrier 120 is patterned in a second step 180c-2 to form the patterned barrier 127. In the process 180b, the patterned barrier 127 may function as a mask for patterning the substrate 110. In the process 180c, the patterned substrate 114 may function as a mask for patterning the barrier 120.

FIGS. 14A-B show a further embodiment of the invention including a resistive layer configured to facilitate removal of water and/or other volatile contaminants from the substrate 110. FIG. 14A shows a basic structure, including the substrate 110, the multi-layer barrier 120, and a resistive layer 190. The resistive layer 190 may be patterned and may comprise any resistive material that does not adversely affect the physical and/or chemical properties of the substrate 110, but in various examples, may include TiN, a-Si (which may be conventionally doped), a silicone, amorphous carbon or another material having a resistivity of 10⁻³-10⁻⁵ Ω·m. In some embodiments, the resistive material is also flexible (e.g., has a stiffness or modulus of elasticity at or below a predetermined maximum). Passing current through the resistive layer 190 heats the resistive layer 190, which in turn heats the substrate 110, evaporating any water and other volatile contaminants in the substrate 110. Eventually, the vaporized water and/or other volatile contaminants escape through exposed edges and any exposed surfaces of the substrate 110.

FIG. 14B shows a further embodiment including patterned substrate 115, a patterned multi-layer barrier 127, a contact 195, and heat 192 from the resistive layer 190. An electrical lead (not shown, but which may be present in the device layer 130, also not shown in FIG. 14B) is connected to the contact 195 so that a current may be passed through the contact 195 to the resistive layer 190 on the opposite side of the patterned substrate 115. By applying a current to the resistive layer 190, the patterned substrate 115 generates heat or thermal energy 192, which vaporizes water in the patterned substrate 115, thereby reducing its moisture content. The resistive layer 190 may thus be exposed by either a through-hole (e.g., FIG. 14B), or over the edge of the patterned substrate 114 or the unpatterned substrate 110 (e.g., FIG. 14A).

Solid state lithium batteries (SSLB) include thin film devices that contain, but are not restricted to, materials such as lithium (Li), lithium cobalt oxide (LCO) and lithium phosphorus oxynitride (LiPON). FIG. 15 shows an exemplary solid-state battery stack 130-1, which includes a cathode current collector 210 (deposited and/or formed on the multi-layer barrier 120), a cathode 220 (e.g., LCO) on the cathode current collector 210, a single-layer solid electrolyte layer 230 (i.e., LiPON) on the cathode 220, a lithium anode 240 on the electrolyte 230, and an anode current collector 250 on the lithium anode 240. The anode 240 may not be present when the SSLB is discharged, and is formed between the electrolyte 230 and the anode current collector 250 during a charging operation. Optionally, a thin lithium anode 240 can be deposited onto the electrolyte layer 230 in a conventional SSLB during fabrication.

Lithium phosphorus oxynitride (LiPON) has been widely adopted as a solid electrolyte layer for solid-state thin film lithium batteries. LiPON may be deposited by RF sputtering using a Li₃PO₄ target. LiPON layers in a solid-state and/or thin film battery (TFB) typically have a thickness of at least 2 μm, to avoid or minimize electrical leakage due to pinholes and other possible defects.

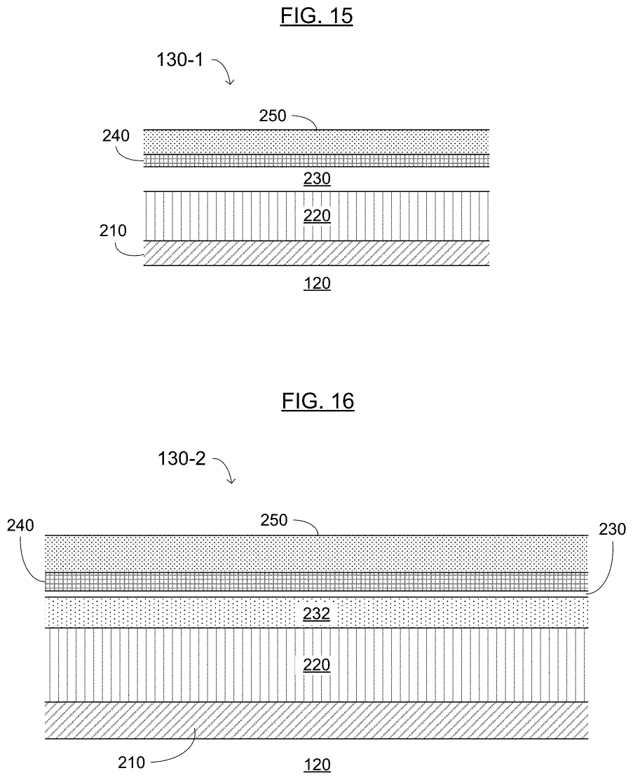

FIG. 16 shows a cross-section of an exemplary solid-state battery stack 130-2, including a multi-layer solid-state electrolyte. The battery stack 130-2 includes a cathode current collector 210 on the multi-layer barrier 120, a cathode 220 (e.g., LCO) on the cathode current collector 210, a multi-layer solid electrolyte 230-232 on the cathode 220, a lithium anode 240 on an anode interface layer 232 of the electrolyte, and an anode current collector 250 on the lithium anode 240. The cathode current collector 210, cathode 220, anode 240 and anode current collector 250 may be substantially the same as in FIG. 15.

Similarly, the anode 240 may not be present when a SSLB including the battery stack 130-2 is discharged. However, it may be initially deposited onto the anode interface layer 232 during fabrication, and it may be formed or re-formed between the anode interface layer 232 and the anode current collector 250 during a charging operation. Thus, the term “anode interface layer” does not imply that it can interface only with the anode 240. It can also interface with the anode current collector 250, or another interface layer (see, e.g., FIG. 18 and the discussion thereof).

The multi-layer solid electrolyte 230-232 comprises the anode interface layer 230 and a lower layer 232, both of solid electrolyte. The anode interface layer 230, which may function as a kind of anode or anode current collector interface, is typically relatively thin, and may have a thickness of 2-100 nm, or any thickness or range of thicknesses therein (e.g., ≤50 nm, 3-10 nm, etc.), although the invention is not limited to such values. The anode interface layer 230 is chemically stable against the Li anode 240, may form stable complex oxides with lithium oxide, and may be highly resistive to electrons and/or electron flow. For example, the anode interface layer 230 may have a resistivity of ≥10¹⁰ Ohm cm (e.g., 10¹⁴-10²⁰ Ohm cm), although the invention is not so limited. The anode interface layer 230 may comprise LiPON (which may be formed by RF sputtering or atomic layer deposition [ALD]) or a (mixed) metal oxide having one or more of the characteristics and/or properties described herein for the anode interface layer 230, such as Al₂O₃, HfO₂, ZnO, or ZrO₂, all of which may be formed by ALD. The anode interface layer 230, when deposited by ALD, can be transformed into a good or excellent Li-ion conductor after lithiation and thermal annealing during device fabrication.

The solid lower electrolyte layer 232 has a higher thickness than the anode interface layer 230. For example, the lower electrolyte layer 232 may have a thickness of 0.5-5 μm, or any thickness or range of thicknesses therein (e.g., 1-3 μm, about 2 μm, etc.), but it is not limited to such values. The lower electrolyte layer 232 generally has a higher lithium ion conductivity than the anode interface layer 230, and may also be deposited at a higher rate (e.g., by sputtering using pulsed DC power) than the anode interface layer 230. The lower electrolyte layer 232 may comprise carbon-doped LiPON or WO₃₊ₓ, which may be oxygen-enriched (0≤x≤1, or any value or range of values therein [e.g., 0.5-0.6]). The value of x may be measured by Rutherford backscattering spectrometry (RBS). Carbon-doped LiPON may be formed by sputtering using pulsed DC power and a mixed graphite-Li₃PO₄ target (e.g., containing 3-15 wt % of graphite). The WO₃₊ₓ layer can also be formed by sputtering using pulsed DC power, but from a metallic tungsten target (e.g., in an oxygen-containing atmosphere/environment). Such so-called “DC-sputtering” is a relatively high-throughput process, in comparison to RF sputtering. The WO₃₊ₓ layer can be transformed into Li₂WO₄, a good Li-ion conductor, after lithiation and thermal annealing (e.g., during device fabrication). The lithium ion conductivity of Li₂WO₄ is at least one order of magnitude higher than that of LiPON.

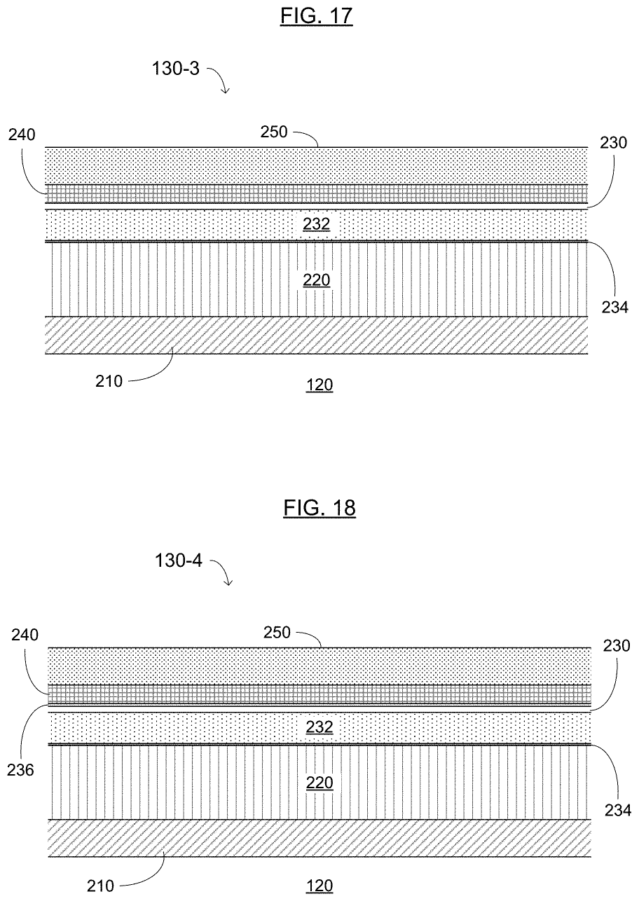

Referring now to FIG. 17, which shows a cross-section of an exemplary solid-state battery stack 130-3 on the multi-layer barrier 120, a third electrolyte layer 234 can be present between the solid bulk electrolyte layer 232 and the cathode 220. This “cathode interface” layer 234 may significantly reduce the interfacial resistance between the cathode 220 and the bulk electrolyte layer 232. In turn, the discharge capacity and discharge rate of a TFB including the present multi-layer solid electrolyte 230-232 and the cathode interface layer 234 may increase significantly relative to an otherwise identical TFB without the cathode interface layer 234. The cathode interface layer 234 may comprise an elemental early transition metal, such as Ti, Zr, Nb or Ta, alumina (Al₂O₃), or an aluminate compatible with both the solid bulk electrolyte layer 232 and the cathode 220. The cathode interface layer 234 may have a thickness of 3-30 nm, or any thickness or range of thicknesses therein (e.g., 10 nm), but it is not so limited.

Referring now to FIG. 18, which shows a cross-section of an exemplary solid-state battery stack 130-4 on the multi-layer barrier 120, when the anode interface 230 is Al₂O₃ (e.g., deposited by ALD), a metal interface layer 236 can be present between the lithium anode 240 and the anode interface layer 230 to reduce the interfacial resistance between the lithium anode 240 and the anode interface layer 230. The metal interface layer 236 may comprise, for example, an elemental middle transition metal, such as Cr, Mo, W, or Ru. The metal interface layer 236 may have a thickness of 10-100 nm, or any thickness or range of thicknesses therein (e.g., 30 nm), but it is not so limited.

### CONCLUSION/SUMMARY

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. An apparatus, comprising:
a substrate;
a first metal nitride layer;
a first oxide layer on or over the first metal nitride layer;
a second metal nitride layer and a second oxide layer on or over the first oxide layer; and
a device layer on or over the first oxide layer or both the first and second oxide layers, wherein:
when the device layer is on or over the first oxide layer, the second metal nitride layer is on or over the device layer, and the second oxide layer is on or over the on or over the second metal nitride layer, and
when the device layer is on or over both the first and second oxide layers, the second metal nitride layer is on or over the second oxide layer.

2. The apparatus of claim 1, wherein the substrate is flexible.

3. The apparatus of claim 2, wherein the substrate comprises a polyimide, polyethylene naphthalate [PEN], polyethylene terephthalate [PET], copper, steel, aluminum, a glass, a silicone, or a flexible ceramic.

4. The apparatus of claim 1, wherein each of the first and second metal nitride layers independently comprises SiN, TiN, AlN, or a combination thereof.

5. The apparatus of claim 1, wherein each of the first and second oxide layers independently comprises SiO₂, a silicon-rich oxide, an aluminosilicate, a silicon oxynitride, an aluminum oxide, or TiO₂.

6. The apparatus of claim 1, wherein the device layer comprises an organic light-emitting diode (OLED), a solar cell, one or more microelectromechanical system (MEMS) devices, or a wireless communication circuit.

7. The apparatus of claim 1, wherein the device layer comprises an integrated circuit (IC), an antenna, a battery, a battery cell, a display, or a sensor.

8. The apparatus of claim 7, wherein the device layer comprises the battery or the battery cell.

9. A method of manufacturing an apparatus, comprising:
forming a first metal nitride layer on a substrate;
forming a first oxide layer on or over the first metal nitride layer;
forming a second metal nitride layer and a second oxide layer on or over the first oxide layer; and
forming a device layer on or over the first oxide layer or both the first and second oxide layers, wherein:
when the device layer is formed on or over the first oxide layer, the second metal nitride layer is formed on or over the device layer, and the second oxide layer is formed on or over the on or over the second metal nitride layer, and
when the device layer is formed on or over both the first and second oxide layers, the second metal nitride layer is formed on or over the second oxide layer.

10. The method of claim 9, wherein each of the first and second metal nitride layers and each of the first and second oxide layers are formed by atomic layer deposition (ALD), plasma-enhanced chemical vapor deposition (PECVD), low-pressure chemical vapor deposition (LPCVD), liquid vapor deposition (LVD), physical vapor deposition (PVD), inkjet printing, gravure printing, offset printing, flexography, nano-imprint printing, micro-contact printing, screen printing, stencil printing, spray-coating, blanket printing, dip-coating, blade-coating, or extrusion coating.

11. The method of claim 9, wherein each of the first and second metal nitride layers and each of the first and second oxide layers are formed by roll-to-roll deposition.

12. The method of claim 9, wherein the substrate comprises a thermoplastic polymer, a metal foil, a polymer- or metal-coated paper, a siloxane polymer, or a flexible ceramic.

13. An apparatus, comprising:
a substrate;
a first metal nitride layer;
a first oxide layer on or over the first metal nitride layer;
either (i) an organic planarization layer or (ii) a gettering layer; and
a device layer on or over the first metal nitride layer, the first oxide layer, and the organic planarization layer or gettering layer.

14. The apparatus of claim 13, comprising the organic planarization layer.

15. The apparatus of claim 14, wherein the organic planarization layer comprises a coatable thermoplastic polymer.

16. The apparatus of claim 14, wherein the organic planarization layer has a thickness greater than the combined thicknesses of the first metal nitride layer and the first oxide layer.

17. The apparatus of claim 13, comprising the gettering layer.

18. The apparatus of claim 17, wherein the gettering layer includes a plurality of trap states.

19. The apparatus of claim 17, wherein the gettering layer comprises amorphous silicon.

20. The apparatus of claim 17, wherein the gettering layer is adjacent to and in contact with the substrate or an uppermost one of the first metal nitride layer and the first oxide layer.
